(19) United States
(12) Patent Application Publication
(10) Pub. No.: US 2006/0050494 A1
(43) Pub. Date: Mar. 9, 2006

(54) DC-AC power inverter

(75) Inventor: Wei-Kuang Chen, Pa Teh City (TW)

Correspondence Address: Raymond Y. Chan, 108 N. Ynez Ave., #128, Monterey Park, CA, 91754, US

(73) Assignee: Cotek Electronic Ind. Co. Ltd.

(21) Appl. No.: 11/123,918

(22) Filed: May 6, 2005

Related U.S. Application Data
(63) Continuation-in-part of application No. 10/933,860, filed on Sep. 3, 2004.

(51) Int. Cl. H05K 7/06

(52) U.S. Cl. 361/777; 361/779

(57) ABSTRACT

A DC-AC inverter includes a Printed Circuit Board (PCB), a plurality of electronic components, and at least a conductive member. The PCB has a top component side and a bottom soldering side, and a copper foil forming an inverting circuit path. The electronic components are mounted on the component side of the PCB to electrically connect with the copper foil. The conductive member is overlapped on the soldering side of the PCB, wherein the conductive member is electrically connected with the copper foil of the PCB to form a safety route of inverting circuit path for electrically bridging an elevated electric current passing therethrough so as to prevent the copper foil from being damaged by the elevated electric current.

### CROSS REFERENCE OF RELATED APPLICATION

This application is a continuation-in-part of a regular application, having an application Ser. No. 10/933,860, filed on Sep. 3, 2004 by the inventor of this application.

### BACKGROUND OF THE PRESENT INVENTION

1. Field of Invention

The present invention relates to an inverter, and more particularly to a DC-AC power inverter which is adapted to sustain large current passage while preserving high circuit efficiency.

2. Description of Related Arts

Due to rapid progression of technology, a considerable number of domestic electric appliances are controlled by electric circuits of various complexities. A common feature of these domestic electric appliances is that they usually comprise a DC-AC inverter which is adapted to invert DC to AC for differing purposes.

Referring to FIG. 1 to FIG. 2 of the drawings, a conventional DC-AC inverter typically comprises a PCB 10 providing a copper foil thereon with a thickness of approximately 0.035-0.07 mm. The DC-AC inverter further comprises a power inverting circuitry, comprising a plurality of electronics parts 13, implemented on the PCB 10 and electrically connected by the copper foil for inverting a particular electric signal, such as a DC signal, to a predetermined AC signal. As a matter of conventional art, typical copper foil would allow a maximum current of approximately 0.35A passing therethrough. When the electric current is greater than 0.35A, the copper foil would be overloaded and may cause such undesirable results as abnormal operation, overheating, and even burning of the entire power inverting circuitry.

In order to increase the current passing though the cooper foil without causing significant damage to the power inverting circuitry, copper banks 12 have been developed for being mounted onto the PCB 10 and electrically connected with the copper foil. The cooper banks 12 are utilized to absorb a vast majority of heat and allow current of high ampere to pass through so that the copper foil is prevented from carrying a large amount of electric current in order to avoid circuit breakdown. In other words, the DC-AC power inverter further comprises a plurality of copper banks 12, each having a plurality of inserting pins 121, mounted on a top surface 11 of the PCB 10 and electrically connected with the copper foil, wherein the inserting pins 121 are soldered with the cooper foil so as to electrically connect the respective copper bank 12 with the copper foil. It is expected that once the PCB 10 has been incorporated with the copper banks 12, the current passing thought the PCB 10 can be largely increased and the capability of the PCB 10 can be substantially enhanced.

The major difficulty in association with these copper banks 12 is that it is difficult to locate the desirable positions on which the copper banks 12 is to be mounted. Specifically, the PCB 10 is meant to be mounted on with the plurality of electronic components 13. Given the need to minimize the size of the PCB 10, the electronic components would be compactly distributed on the PCB 10 so that one can hardly find sufficient space on the PCB 10 for mounting the copper banks 12 without obstruction by other electronics components. Of course, one may increase the size of the PCB 10 in order to allocate sufficient space for mounting of the copper banks 12, but this is by no means desirable.

Another problem for the copper banks 12 is that even if one is able to find sufficient space on the PCB 10, the electrical connection between the inserting pins 121 and the copper foil is usually by means of point contact such that it is very easy for current to be concentrated in the vicinity of the contacting point. As such, heat loss or voltage drop of the power inverting circuitry may occur. These are very undesirable results in high frequency and high voltage power inversion.

### SUMMARY OF THE PRESENT INVENTION

A main object of the present invention is to provide a DC-AC inverter which allows larger current passing therethrough as compared with conventional DC-AC inverters. Moreover, the present invention is able to sustain such a large current without developing into significant damages or malfunctioning.

Another object of the present invention is to provide a DC-AC inverter comprising a plurality of conductive members, such as copper banks, mounted on the PCB for sustaining large current input to the PCB while do not encounter the difficulties as mentioned in the above conventional arts.

Another object of the present invention is to provide a DC-AC inverter which can be manufactured at low cost while allowing a large amount of current to pass therethough without being damaged.

Accordingly, in order to accomplish the above objects, the present invention provides a DC-AC inverter, comprising:
a printed circuit board (PCB) having a top component side and a bottom soldering side, wherein the printed circuit board further has a copper foil provided thereon to form an inverting circuit path;
a plurality of electronic components mounted on the component side of the PCB to electrically connect with the copper foil for inverting a DC input signal into a predetermined AC output signal through the inverting circuit path; and
at least a conductive member overlapped on the soldering side of the PCB, wherein the conductive member is electrically connected with the copper foil of the PCB to form a safety route of inverting circuit path for electrically bridging an elevated electric current passing therethrough so as to prevent the copper foil from being damaged by the elevated electric current.

These and other objectives, features, and advantages of the present invention will become apparent from the following detailed description, the accompanying drawings, and the appended claims.

### BRIEF DESCRIPTION OF THE DRAWINGS

FIG. 1 is an exploded perspective of a conventional DC-AC inverter.

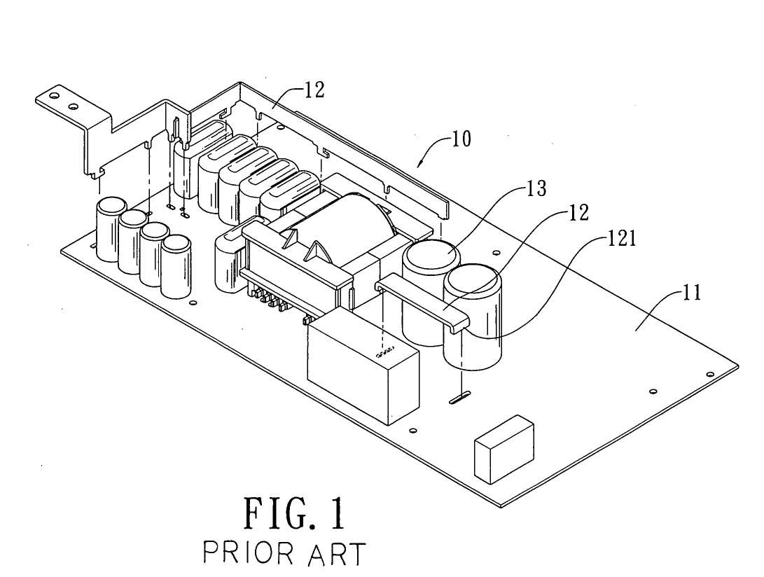

FIG. 2 is a perspective view of a conventional DC-AC inverter.

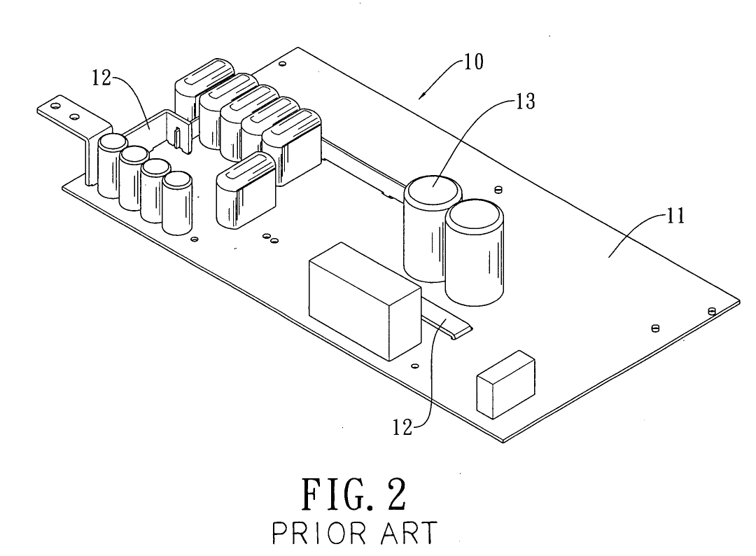

FIG. 3 is an exploded perspective view of a DC-AC inverter according to a preferred embodiment of the present invention.

FIG. 4 is a perspective view of the DC-AC inverter according to the above preferred embodiment of the present invention.

FIG. 5 is a bottom view of the DC-AC inverter according to the above preferred embodiment of the present invention.

FIG. 6 is a schematic bottom view of the DC-AC inverter according to the above preferred embodiment of the present invention.

FIG. 7 is a section side view of the DC-AC inverter according to the above preferred embodiment of the present invention.

### DETAILED DESCRIPTION OF THE PREFERRED EMBODIMENT

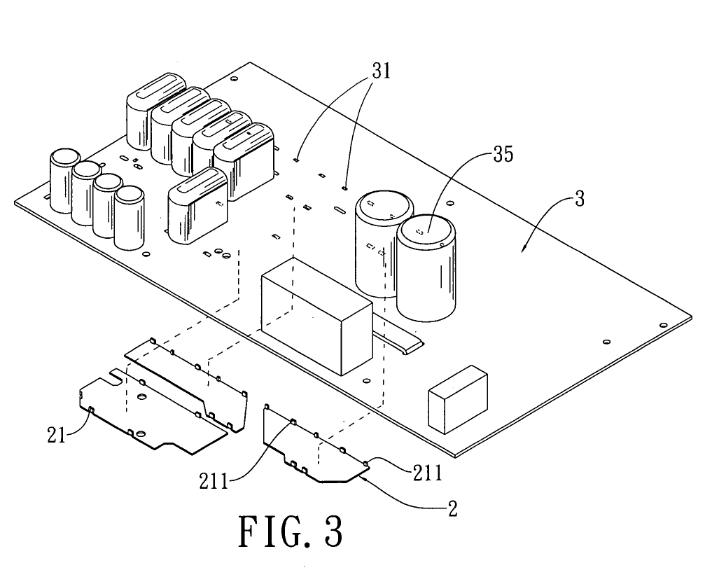

Referring to FIG. 3 to FIG. 6 of the drawings, a DC-AC inverter according to a preferred embodiment of the present invention is illustrated, in which the DC-AC inverter comprises a Printed circuit board (PCB) 3, a plurality of electronic components 35, and at least a conductive member 2.

The printed circuit board (PCB) 3, such as a regular circuit board, has a top component side 33 and a bottom soldering side 32, wherein the PCB 3 further has a copper foil 36 provided thereon to form an inverting circuit path.

On the other hand, the plurality of electronic components 35 is mounted on the component side 33 of the PCB 3 to electrically connect with the copper foil 36 for inverting a DC input signal into a predetermined AC output signal through the inverting circuit path.

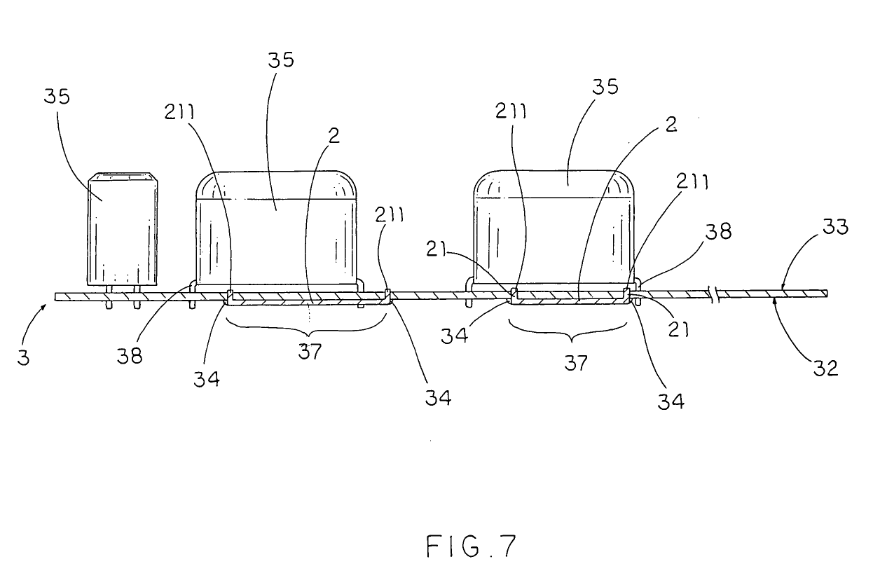

Referring also to FIG. 7 of the drawings, according to the preferred embodiment of the present invention, the copper foil 36 is attached on the bottom soldering side 32 of the PCB 3 wherein each of the electronic components 35, such as capacitors or resistors, is supported on the components side 33 of the PCB 3, and has at least one conducting terminal 38 penetrating through the PCB 3 from the components side 33 to the soldering side 32 so as to electrically connect with the copper foil 36 at the soldering side 32 of the PCB 3.

The conductive member 2 is overlapped on the soldering side 32 of the PCB 3, wherein the conductive member 2 is electrically connected with the copper foil 36 of the PCB 3 to form a safety route of inverting circuit path for electrically bridging an elevated electric current passing therethrough so as to prevent the copper foil 36 from being damaged by the elevated electric current.

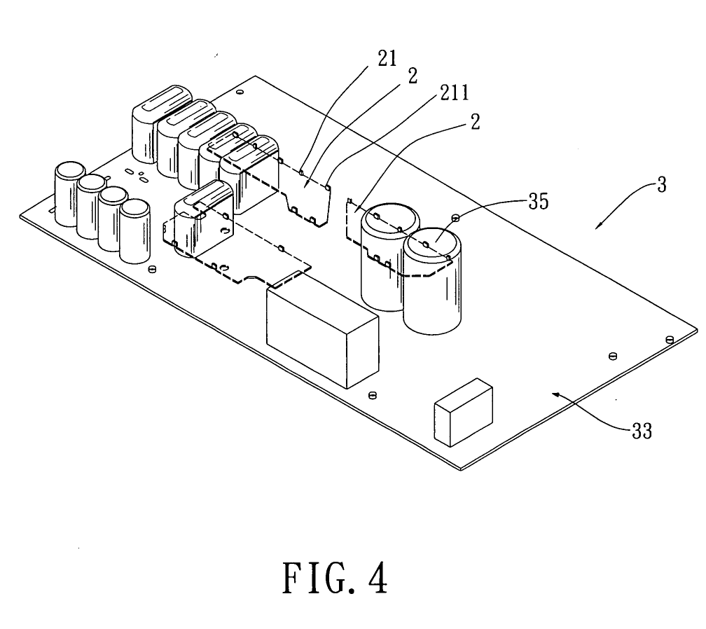

In order to match the PCB in different shapes, the contour of the conductive member 2 can be suitably arranged for different situations. Referring to FIG. 3 to FIG. 4 of the drawings, the conductive member 2 has several inserting pins 21 surrounding the periphery thereof and each of the inserting pins 21 outwardly extend to form an engaging end 211. The conductive member 2 and the inserting pins 21 are embodied as being made of copper for electrical conduction.

In other words, the conductive member 2 has a plurality of the inserting pins 21 outwardly and integrally extended alone a peripheral edge thereof, wherein each of the inserting pins 21 is spacedly apart from each other to overlappedly mount the conductive member 2 on the soldering side 32 of the PCB 3 so as to create the safety route for a relatively large amount of current passing through this safety route.

The PCB 3 has a plurality of fitting holes 31 formed at the areas being passed through with larger current and the holes correspond to the inserting pins 21 so that the inserting pins 21 can engage with the circuit board 3 by way of the engaging ends 211 passing through the fitting holes 31 and reaching the soldered surface 32.

In the meantime, the inserting pins 21 of the conductive member 2 can expose at surfaces of electronic parts 35 to be fixedly attached to the soldered surface 32 by way of soldering treatment with the tin surface. In this way, the conductive member 2 can facially contact with the circuit board 3 and the copper foil 36 on the circuit board 3 can endure much more current passing through the circuit board 3, the fabrication cost of the entire circuit board can be lowered largely and the utilization efficiency of circuit board can be enhanced greatly. In addition, obstruction of other electronic parts 35 can be avoided so as to facilitate the fabrication process and to increase market competitive power and practicality.

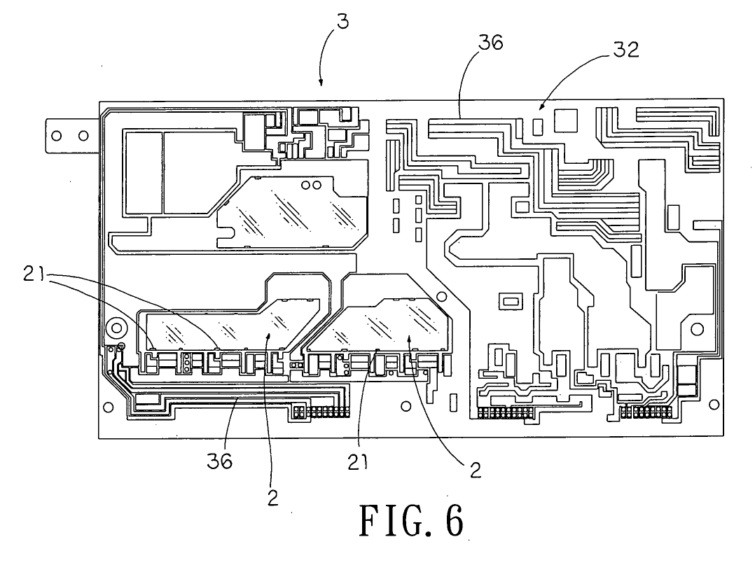

Accordingly, as shown in FIG. 6 to FIG. 7 of the drawings, the PCB 3 defines at least one elevated current zone 37 where a substantial and elevated amount of current is expected to pass therethough. Thus, the PCB 3 has the plurality of through fitting holes 31 spacedly distributed and formed at the elevated current zone 37 on the bottom soldering side 32 of the PCB 3 wherein the inserting pins 21 of the conductive member 2 is arranged to sildably penetrate into the respective fitting holes 31 so as to overlapply mounted on the bottom soldering side 32 of the PCB 3. It is worth mentioning that the fitting holes 31 are formed on the copper foil 36 of the PCB 3 so that the each of the inserting pins 21 are allowed to electrically connect with the copper foil 36 through penetration of the respective fitting hole 31.

According to the preferred embodiment, each of the conductive members 2 is embodied as a copper panel having a shape corresponding with a contour of the respective elevated current zone 37 such that the conductive member 2 is capable of overlapping the respective elevated current zone 37 for providing the safety route across that elevated current zone 37.

It is important to point out at this stage that when the conductive member 2 is mounted to overlap the elevated current zone 37, electric current, due to planar shape of the conductive member 2, would pass through the conductive member 2 across the elevated current zone 37 so as to supply sufficient electric current to the relevant electronic components 35 on the top component side 33 of the PCB 3. Since the conductive member 2 has a relatively large surface area than the copper foil 36, by simple electronics theory, the conductive member 2 can then sustain larger electric current than the copper foil 36, without being damaged by the larger electric current. The larger electric current would have damaged the copper foil 36 if the larger electric current was allowed to pass therethrough.

In other words, the advantages of the present invention may be summarized as follows: The conductive member is inserted to the soldering side 32 and is adhesively attached to the circuit board (PCB 3) by way of tin soldering so that it can enhance efficiency, reduce heat loss and lower skin-effect loss resulting from high frequency.

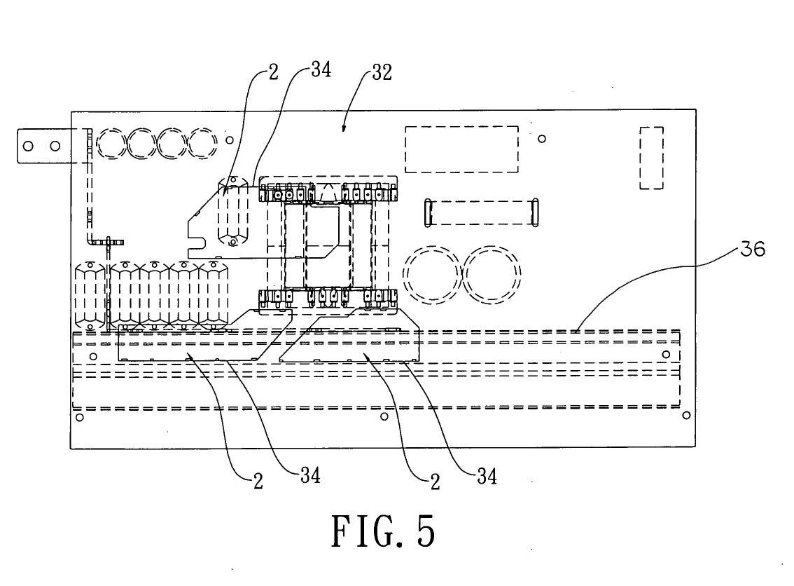

Thus, as shown in FIG. 5 and FIG. 7 of the drawings, the PCB 3 further has a plurality of soldering connectors 34 provided on the soldering side 32 of the PCB 3 for electrically connecting the inserting pins 21 with the copper foil 36 and as the same time providing support to the conductive members 2. In other words, each of the inserting pins 21 is soldered on the soldering side 32 of the PCB 3 so as to overlappedly attach the respective conductive member 2 on the elevated current zone of the PCB 3. It is worth mentioning that the soldering connectors 34 can be embodied as integrally connected with each other to form a soldering line connecting the conductive member 2 with the PCB 3.

Moreover, it is important to stress that because not all of the electronics components 35 requires the same strength of electric current, the DC-AC inverter can comprise a plurality of the conductive members 2 so as to overlap a corresponding number of elevated current zones 37 which are spacedly apart from each other so that each of the conductive members 2 is responsible for overlapping on the respective elevated current zone 37.

Obviously, the DC-AC inverter further comprises a DC inlet for electrically connecting with a DC input signal, and an AC outlet adapted for delivering a predetermined AC signal output. Thus, the DC inlet and the AC outlet are electrically communicated with the copper foil 36 so as to electrically connected with the electronic components 35 as well as the conductive members 2.

From the forgoing descriptions, it can be shown that the above objects can be substantially accomplished. The present invention provides a DC-AC inverter which allows larger current to pass therethrough without having significant possibility of being damaged.

One skilled in the art will understand that the embodiment of the present invention as shown in the drawings and described above is exemplary only and not intended to be limiting.

It will thus be seen that the objects of the present invention have been fully and effectively accomplished. It embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A DC-AC inverter, comprising:
a printed circuit board (PCB) having a top component side and a bottom soldering side, wherein said printed circuit board further has a copper foil provided thereon to form an inverting circuit path;
a plurality of electronic components mounted on said component side of said PCB to electrically connect with said copper foil for inverting a DC input signal into a predetermined AC output signal through said inverting circuit path; and
at least a conductive member overlapped on said soldering side of said PCB, wherein said conductive member is electrically connected with said copper foil of said PCB to form a safety route of said inverting circuit path for electrically bridging an elevated electric current passing therethrough so as to prevent said copper foil from being damaged by said elevated electric current.

2. The DC-AC inverter, as recited in claim 1, wherein said conductive member has a plurality of inserting pins outwardly and integrally extended alone a peripheral edge thereof, wherein each of said inserting pins is spacedly apart from each other to overlappedly mount on said conductive member on said soldering side of said PCB so as to create said safety route for said elevated electric current passing through said safety route.

3. The DC-AC inverter, as recited in claim 1, wherein said PCB defines at least one elevated current zone where said elevated electric current is arranged to pass though, wherein said conductive member is attached on said soldering side of said PCB at said elevated current zone so as to provide said safety route across said elevated current zone in order to prevent said copper foil from being damaged by said elevated electric current.

4. The DC-AC inverter, as recited in claim 2, wherein said PCB defines at least one elevated current zone where said elevated electric current is arranged to pass though, wherein said conductive member is attached on said soldering side of said PCB at said elevated current zone so as to provide said safety route across said elevated current zone in order to prevent said copper foil from being damaged by said elevated electric current.

5. The DC-AC inverter, as recited in claim 4, wherein said PCB has a plurality of through fitting holes spacedly distributed and formed at said elevated current zone on said soldering side of said PCB, wherein said inserting pins of said conductive member is arranged to sildably penetrate into said respective fitting holes so as to overlapply mount on said soldering side of said PCB.

6. The DC-AC inverter, as recited in claim 4, wherein each of said conductive members is embodied as a metallic panel having a shape corresponding with a contour of said respective elevated current zone such that said conductive member is capable of overlapping said elevated current zone for providing said safety route across said elevated current zone.

7. The DC-AC inverter, as recited in claim 5, wherein each of said conductive members is embodied as a metallic panel having a shape corresponding with a contour of said respective elevated current zone such that said conductive member is capable of overlapping said elevated current zone for providing said safety route across said elevated current zone.

8. The DC-AC inverter, as recited in claim 1, wherein said copper foil is attached on said soldering side of said PCB wherein each of said electronic components is supported on said components side of said PCB, and has at least one conducting terminal penetrating through said PCB from said components side to said soldering side so as to electrically connect with said copper foil at said soldering side of said PCB.

9. The DC-AC inverter, as recited in claim 6, wherein said copper foil is attached on said soldering side of said PCB wherein each of said electronic components is supported on said components side of said PCB, and has at least one conducting terminal penetrating through said PCB from said components side to said soldering side so as to electrically connect with said copper foil at said soldering side of said PCB.

10. The DC-AC inverter, as recited in claim 7, wherein said copper foil is attached on said soldering side of said PCB wherein each of said electronic components is supported on said components side of said PCB, and has at least one conducting terminal penetrating through said PCB from said components side to said soldering side so as to electrically connect with said copper foil at said soldering side of said PCB.

11. The DC-AC inverter, as recited in claim 5, wherein said fitting holes are formed on said copper foil of said PCB at said elevated current zone so that each of said inserting pins are allowed to electrically connect with said copper foil through penetration of said respective fitting hole.

12. The DC-AC inverter, as recited in claim 7, wherein said fitting holes are formed on said copper foil of said PCB at said elevated current zone so that each of said inserting pins are allowed to electrically connect with said copper foil through penetration of said respective fitting hole.

13. The DC-AC inverter, as recited in claim 10, wherein said fitting holes are formed on said copper foil of said PCB at said elevated current zone so that each of said inserting pins are allowed to electrically connect with said copper foil through penetration of said respective fitting hole.

14. The DC-AC inverter, as recited in claim 2, wherein said PCB further has a plurality of soldering connectors attached on said soldering side of said PCB at said inserting pins respectively for electrically connecting said inserting pins with said copper foil and providing support to said conductive members on said soldering side of said PCB.

15. The DC-AC inverter, as recited in claim 11, wherein said PCB further has a plurality of soldering connectors attached on said soldering side of said PCB at said inserting pins respectively for electrically connecting said inserting pins with said copper foil and providing support to said conductive members on said soldering side of said PCB.

16. The DC-AC inverter, as recited in claim 12, wherein said PCB further has a plurality of soldering connectors attached on said soldering side of said PCB at said inserting pins respectively for electrically connecting said inserting pins with said copper foil and providing support to said conductive members on said soldering side of said PCB.

17. The DC-AC inverter, as recited in claim 13, wherein said PCB further has a plurality of soldering connectors attached on said soldering side of said PCB at said inserting pins respectively for electrically connecting said inserting pins with said copper foil and providing support to said conductive members on said soldering side of said PCB.

18. The DC-AC inverter, as recited in claim 15, wherein said conductive member is made of copper.

19. The DC-AC inverter, as recited in claim 16, wherein said conductive member is made of copper.

20. The DC-AC inverter, as recited in claim 17, wherein said conductive member is made of copper.
